(19) United States
(12) Patent Application Publication
(10) Pub. No.: US 2026/0282281 A1
(43) Pub. Date: Sep. 17, 2026

(54) COOLING DEVICE

(71) Applicant: Panasonic Projector & Display Corporation, Osaka (JP)

(72) Inventor: Hideyuki NAGAO, Fukuoka (JP)

(73) Assignee: Panasonic Projector & Display Corporation, Osaka (JP)

(21) Appl. No.: 19/670,256

(22) Filed: May 7, 2026

Related U.S. Application Data
(63) Continuation of application No. 18/266,747, filed on Dec. 7, 2021.

(30) Foreign Application Priority Data
Dec. 14, 2020 (JP) 2020-206636

(51) Int. Cl. H05K 7/20

(52) U.S. Cl. CPC H05K 7/20272; H05K 7/2039

(57) ABSTRACT

A cooling device includes a heat absorbing member, a heat radiating fin provided on the heat absorbing member, and a casing attached to cover the heat radiating fin. The casing includes: an inflow port into which a coolant flows, an outflow port from which the coolant flows out, and a plurality of flow paths, through which the coolant flows. The plurality of flow paths includes at least one downstream flow path communicating with the outflow port and faces the heat radiating fin. The plurality of flow paths is arranged to sandwich the heat radiating fin between the plurality of flow paths.

### CROSS REFERENCE TO RELATED APPLICATION

This is a Continuation of U.S. patent application Ser. No. 18/266,747, filed Jun. 12, 2023, the entire disclosure of which is incorporated herein by reference in its entirety. U.S. patent application Ser. No. 18/266,747 is a National Phase application of International Patent Application No. PCT/JP2021/044830, filed Dec. 7, 2021, which claims priority to Japanese Patent Application No. 2020-206636, filed Dec. 14, 2020.

### TECHNICAL FIELD

The present disclosure relates to a cooling device.

### BACKGROUND ART

For example, Patent Document 1 discloses a cooling device that cools a heating element with cooling water. The cooling water travels straight along the linear flow path. A plurality of heat radiating fins thermally connected to the plurality of heating elements are arranged in parallel in the flow path. Each of the heat radiating fins extends in the flow direction of the cooling water, and is arranged in parallel at intervals in which the cooling water flows in a direction orthogonal to the flow direction. The flow path cross-sectional area of the flow path through which the cooling water travels straight decreases toward the downstream side. Accordingly, the plurality of heating elements arranged in the flow direction of the cooling water is efficiently cooled.

### PRIOR ART DOCUMENT

### Patent Document

Patent Document 1: JP 2013-197159 A

### SUMMARY OF THE INVENTION

### Problems to be Solved by the Invention

However, in the case of the cooling device of Patent Document 1 described above, in order that the cooling water travels straight, the outflow port is positioned on the opposite side to the inflow port of the cooling water. That is, in the cooling device, positions where the inflow port and the outflow port are provided are limited. Accordingly, the installation space of the pipe to be connected to each of the inflow port and the outflow port is also limited, and as a result, the installation place of the cooling device may be limited.

Thus, an object of the present disclosure is to implement a cooling device having a configuration capable of changing a layout of an inflow port and an outflow port of a coolant while maintaining cooling efficiency.

### Means for Solving the Problems

In order to solve the above problem, according to one aspect of the present disclosure, a cooling device is provided including: a heat absorbing member including a first surface to which an object to be cooled is to be attached and a second surface opposite to the first surface; a plurality of heat radiating fins provided on the second surface of the heat absorbing member, the plurality of heat radiating fins being arranged along a first direction, the plurality of heat radiating fins each being extending in a second direction orthogonal to the first direction; and a casing attached to a second surface of the heat absorbing member to cover the plurality of heat radiating fins. The casing includes: an inflow port into which a coolant flows, an outflow port from which a coolant flows out, an upstream flow path communicating with the inflow port and facing top portions of the plurality of heat radiating fins, and a downstream flow path communicating with the outflow port, extending in the first direction, and facing end portions in the second direction of the plurality of heat radiating fins. In addition, the outflow port is provided at an end portion on one side in the first direction of the casing. Then, a flow path cross-sectional area in the first direction of the downstream flow path is increased with distance from the outflow port.

### Effects of the Invention

According to the present disclosure, it is possible to implement a cooling device having a configuration capable of changing a layout of an inflow port and an outflow port of a coolant while maintaining cooling efficiency.

### BRIEF DESCRIPTION OF THE DRAWINGS

FIG. 1 is a perspective view of a cooling device according to an embodiment of the present disclosure.

FIG. 2 is an exploded perspective view of the cooling device.

FIG. 3 is a perspective view of a casing in the cooling device as viewed from below.

FIG. 4 is a bottom view of the casing in the cooling device.

FIG. 5 is a cross-sectional view of the cooling device taken along line A-A in FIG. 4.

FIG. 6 is a cross-sectional view of the cooling device taken along line B-B in FIG. 4.

FIG. 7 is a cross-sectional view of the cooling device taken along line C-C in FIG. 4.

FIG. 8 is a cross-sectional view of the cooling device taken along line D-D in FIG. 5.

FIG. 9 is a perspective view of the cooling device showing the inside of the downstream flow path.

FIG. 10 is a view schematically showing a shape of the downstream flow path.

FIG. 11 is a view schematically showing a shape of a downstream flow path in a cooling device according to another embodiment.

FIG. 12 is a view schematically showing shapes of an upstream flow path and a downstream flow path in a cooling device according to still another embodiment.

### MODES FOR CARRYING OUT THE INVENTION

Hereinafter, embodiments will be described in detail with reference to the drawings as appropriate. However, a detailed description more than necessary may be omitted. For example, a detailed description of already well-known matters and a redundant description of substantially the same configuration may be omitted. This is to avoid the following description from becoming unnecessarily redundant and to facilitate understanding by those skilled in the art.

It should be noted that the inventors provide the accompanying drawings and the following description in order for those skilled in the art to fully understand the present disclosure, and do not intend to limit the subject matter described in the claims by the accompanying drawings and the following description.

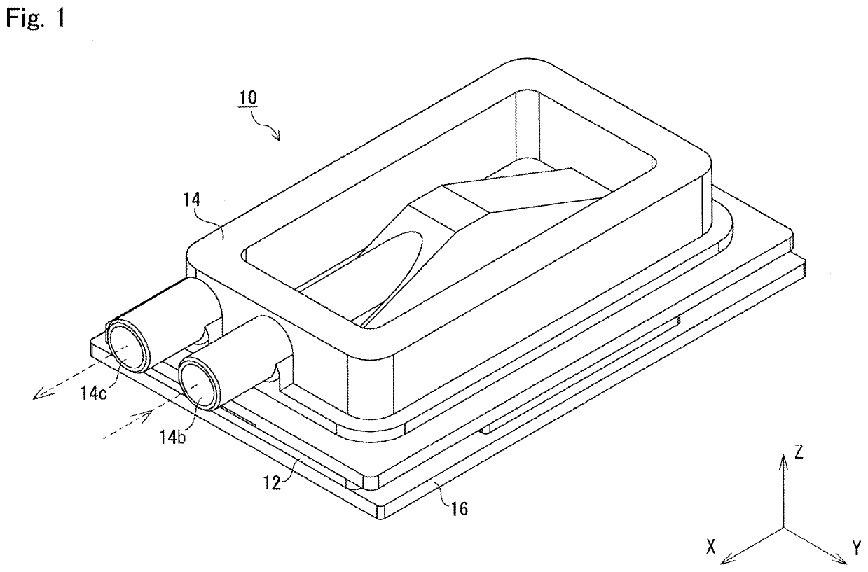

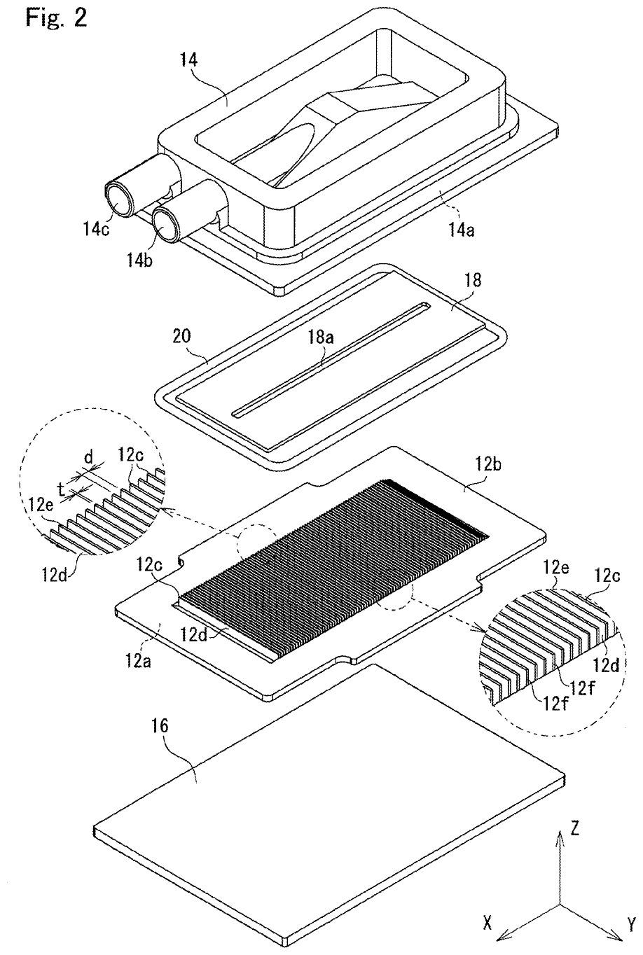

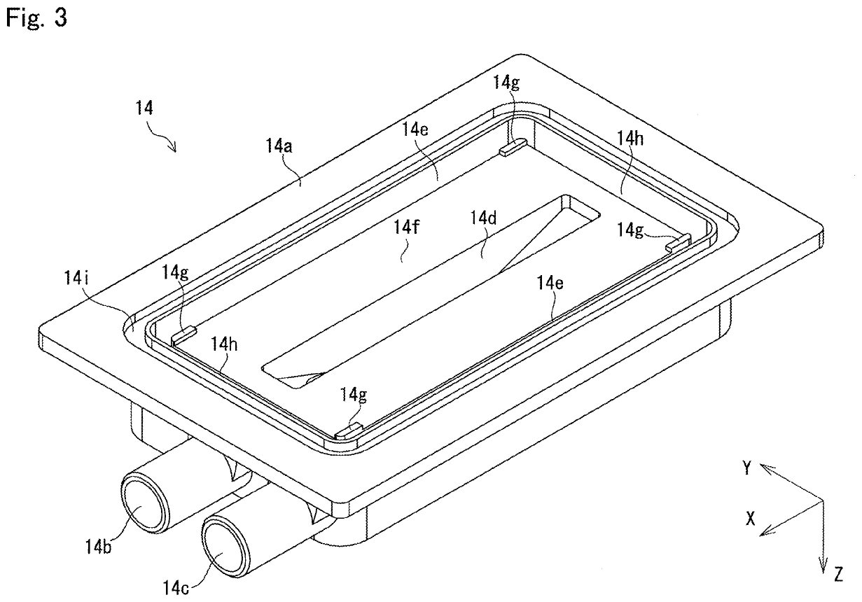

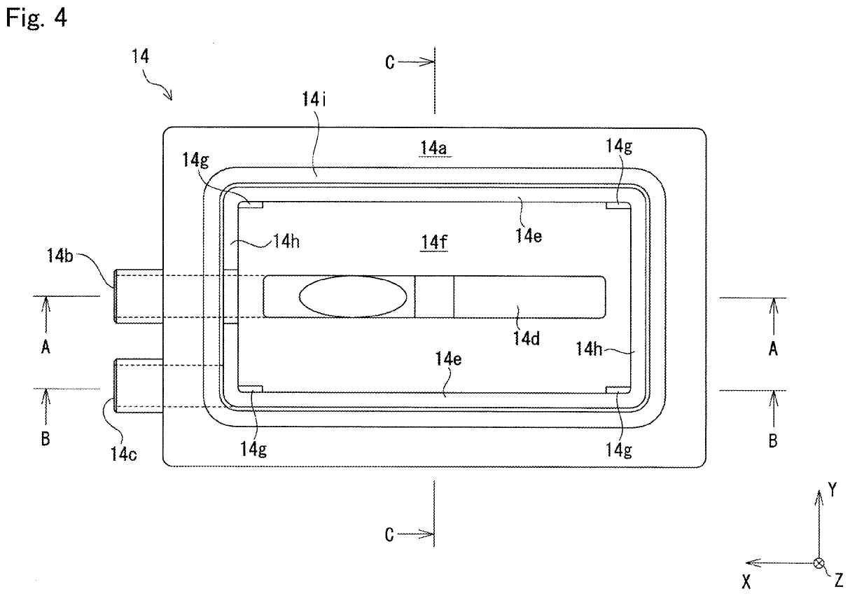

FIG. 1 is a perspective view of a cooling device according to a first embodiment of the present disclosure. In addition, FIG. 2 is an exploded perspective view of the cooling device. Furthermore, FIG. 3 is a perspective view of a casing in the cooling device as viewed from below. Then, FIG. 4 is a bottom view of the casing in the cooling device.

It should be noted that the X-Y-Z orthogonal coordinate system shown in the drawings is for facilitating understanding of embodiments of the present disclosure, and does not limit the embodiments. The X-axis direction indicates the depth direction (first direction), the Y-axis direction indicates the width direction (second direction), and the Z-axis direction indicates the height direction.

In addition, in the present specification, terms that limit directions, such as “up”, “down”, and “bottom”, are used, and these terms are intended to facilitate understanding of the embodiments and do not limit the attitude of the cooling device.

As shown in FIGS. 1 and 2, in the present embodiment, the cooling device 10 is a device that cools an object to be cooled with a coolant such as water, and includes a heat absorbing member 12 that absorbs heat from the object to be cooled, and a casing 14 which is attached to the heat absorbing member 12 and through which the cooling water flows inside.

The heat absorbing member 12 is a plate-shaped member made of a metal material such as aluminum having high thermal conductivity, and includes a first surface 12a to which an object to be cooled is attached and a second surface 12b opposite to the first surface 12a. It should be noted that in the case of the present embodiment, the heating element is attached to the first surface 12a of the heat absorbing member 12 with interposition of a plate-shaped heat spreader 16 made of a metal material having high thermal conductivity. In place of this, the heating element may be directly attached to the heat absorbing member 12.

In addition, a plurality of heat radiating fins 12c are provided at the center of the second surface 12b of the heat absorbing member 12. The plurality of heat radiating fins 12c are, for example, micro fins integrally formed with the heat absorbing member 12. Each of the plurality of heat radiating fins 12c protrudes in the height direction (Z-axis direction) from the heat absorbing member 12 toward the casing 14, and has a thin plate shape in which the size in the width direction (Y-axis direction) is larger than the size in the height direction. In addition, each of the plurality of heat radiating fins 12c includes a heat transfer surface 12d (parallel to the Y-Z plane) that exchanges heat with the coolant and extends in the width direction and the height direction.

Furthermore, the plurality of heat radiating fins 12c have a predetermined thickness t (size in the depth direction (X-axis direction)), and are arranged along the depth direction at predetermined intervals d. It should be noted that each of the thickness t and the interval d may be a constant value or a different value within a predetermined range.

As shown in FIGS. 1 and 2, the casing 14 is attached to the second surface 12b of the heat absorbing member 12 so as to cover the plurality of heat radiating fins 12c. The casing 14 is made of a resin material, for example.

As shown in FIGS. 3 and 4, the casing 14 includes a bottom surface 14a to be attached to the heat absorbing member 12. Specifically, the bottom surface 14a has an annular shape, and is attached to a portion of the second surface 12b of the heat absorbing member 12 except for a central portion where the plurality of heat radiating fins 12c are provided. By the casing 14 being attached to the heat absorbing member 12 through the bottom surface 14a, the plurality of heat radiating fins 12c are covered with the casing 14. It should be noted that the heat absorbing member 12 and the casing 14 are fixed to each other by, for example, screws (not shown).

As shown in FIGS. 3 and 4, the casing 14 includes an inflow port 14b into which the coolant flows, an outflow port 14c from which the coolant flows out, an upstream flow path 14d positioned upstream of the plurality of heat radiating fins 12c in the flow direction of the coolant, and a downstream flow path 14e positioned downstream of the plurality of heat radiating fins 12c.

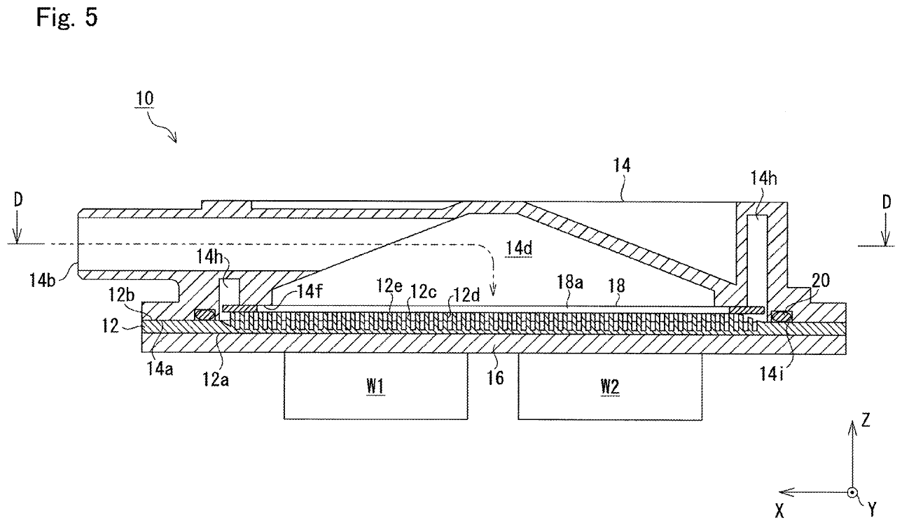

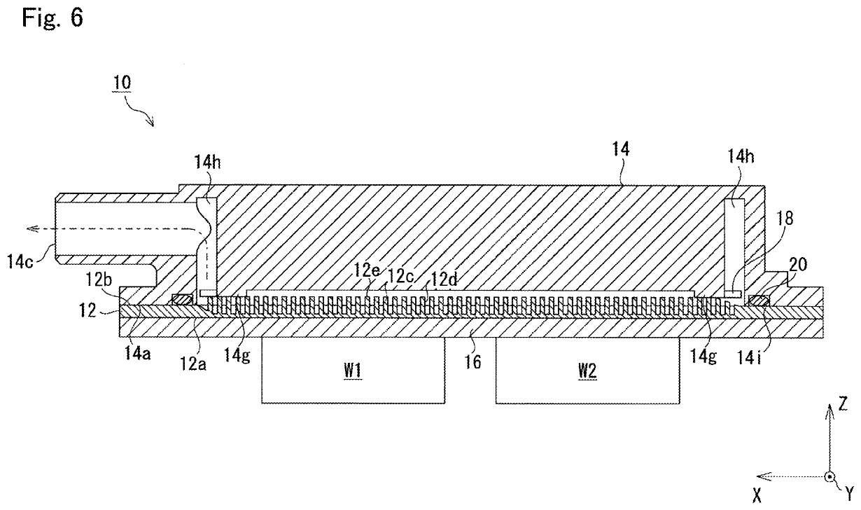

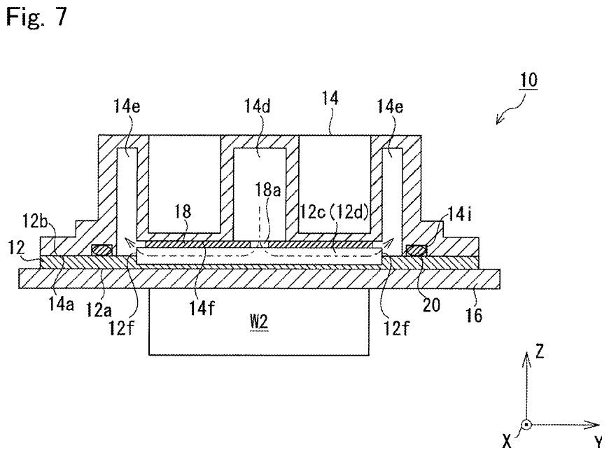

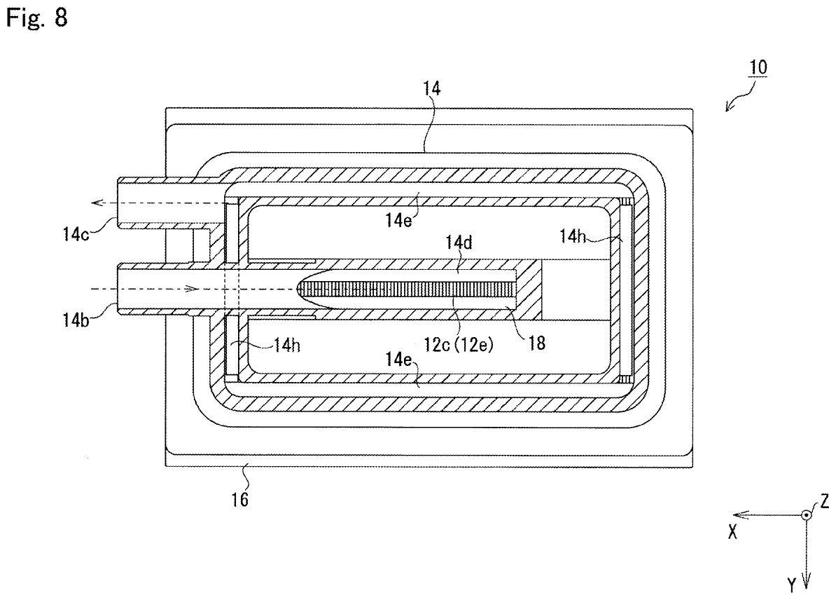

FIG. 5 is a cross-sectional view of the cooling device taken along line A-A in FIG. 4. In addition, FIG. 6 is a cross-sectional view of the cooling device taken along line B-B in FIG. 4. Furthermore, it is a cross-sectional view of the cooling device taken along line C-C in FIG. 7. Then, FIG. 8 is a cross-sectional view of the cooling device taken along line D-D in FIG. 5.

As shown in FIG. 8, in the case of the present embodiment, the inflow port 14b and the outflow port 14c of the coolant are provided side by side at an end portion on one side in the depth direction (X-axis direction) of the casing 14. In addition, the inflow port 14b and the outflow port 14c are arranged side by side in the width direction (Y-axis direction) and face the depth direction. The low-temperature coolant flows into the inflow port 14b, and the high-temperature coolant flows out from the outflow port 14c. After exiting from the outflow port 14c, the coolant to be used in the cooling device 10 may be cooled by a fan or the like and be returned to the inflow port 14b again by a pump or the like.

As shown in FIGS. 5 and 7, the upstream flow path 14d of the casing 14 communicates with the inflow port 14b into which the refrigerant flows. In addition, the upstream flow path 14d is provided in the casing 14 so as to face the top portions 12e of the plurality of heat radiating fins 12c.

In the case of the present embodiment, as shown in FIG. 3, the upstream flow path 14d has an opening on the facing surface 14f of the casing 14 that faces the top portions 12e of the plurality of heat radiating fins 12c. As shown in FIG. 4, the facing surface 14f is surrounded by an annular bottom surface 14a as viewed in the height direction (Z-axis direction). In addition, the facing surface 14f is farther from the second surface 12b of the heat absorbing member 12 than the bottom surface 14a. A plate-shaped seal member 18 made of an elastic material such as silicone rubber is sandwiched between the facing surface 14f and the top portions 12e of the plurality of heat radiating fins 12c. The seal member 18 includes a through hole 18a for exposing the central portion in the width direction (Y-axis direction) at the top portions 12e of the plurality of heat radiating fins 12c to the upstream flow path 14d. As shown in FIG. 2, the through hole 18a of the seal member 18 is an elongated hole longer in the parallel direction (X-axis direction) of the plurality of heat radiating fins 12c. With this configuration, the upstream flow path 14d faces the top portions 12e of the plurality of heat radiating fins 12c, particularly, faces the central portion of the top portions 12e through the through hole 18a of the seal member 18. It should be noted that as shown in FIGS. 3 and 4, each of the four corners of the facing surface 14f is provided with a protruding portion 14g for positioning the seal member 18.

As shown in FIGS. 7 and 8, the downstream flow path 14e of the casing 14 communicates with the outflow port 14c from which the refrigerant flows out. In addition, the downstream flow path 14e extends in the depth direction (X-axis direction) and is provided in the casing 14 so as to face the end portion 12f in the width direction (Y-axis direction) of each of the plurality of heat radiating fins 12c.

In the case of the present embodiment, as shown in FIGS. 4 and 8, two downstream flow paths 14e are present. Specifically, one downstream flow path (first downstream flow path) 14e facing one end portion 12f in the width direction (Y-axis direction) of each of the plurality of heat radiating fins 12c and the other downstream flow path (second downstream flow path) 14e facing the other end portion 12f in the width direction of each of the plurality of heat radiating fins 12c are provided in the casing 14. That is, the two downstream flow paths 14e extend in the depth direction (X-axis direction) in parallel to each other so as to sandwich the plurality of heat radiating fins 12c in the width direction.

It should be noted that in the case of the present embodiment, as shown in FIGS. 4 and 8, the outflow port 14c communicates with one downstream flow path 14e and does not communicate with the other downstream flow path 14e. Thus, the casing 14 includes a connection flow path 14h that connects the two downstream flow paths 14e. In the case of the present embodiment, two connection flow paths 14h are present. A connection flow path 14h connecting distal ends of the two downstream flow paths 14e farther from the outflow port 14c, and a connection flow path 14h connecting proximal ends of the two downstream flow paths 14e closer to the outflow port 14c are present. That is, in the case of the present embodiment, as shown in FIG. 8, the two downstream flow paths 14e and the two connection flow paths 14h constitute an annular flow path communicating with the outflow port 14c.

In addition, in the case of the present embodiment, as shown in FIGS. 6 and 7, the second surface 12b of the heat absorbing member 12 is partially exposed to the two downstream flow paths 14e and the two connection flow paths 14h. That is, the two downstream flow paths 14e and the two connection flow paths 14h are recessed, and the second surface 12b of the heat absorbing member 12 covers them. With this configuration, the cooling device 10 includes an annular seal member 20 as shown in FIG. 2 so that the coolant in the two downstream flow paths 14e and the two connection flow paths 14h does not leak from between the heat absorbing member 12 and the casing 14. As shown in FIGS. 3 and 4, the annular seal member 20 is housed in an annular groove 14i formed in the bottom surface 14a so as to surround an annular flow path including two downstream flow paths 14e and two connection flow paths 14h.

According to this configuration, the cooling device 10 operates as follows.

As shown in FIGS. 5 and 6, first, a plurality of heating elements W1 and W2 are attached to the first surface 12a of the heat absorbing member 12 with interposition of the heat spreader 16 in a state of being side-by-side in the depth direction (X-axis direction). It should be noted that the heating elements W1 and W2 are, for example, laser elements that emit laser light.

As shown in FIGS. 5 and 8, the coolant flows into the cooling device 10 through the inflow port 14b. It should be noted that the flow of the coolant is indicated by an alternate long and short dash line.

As shown in FIG. 5, the coolant flowing in from the inflow port 14b reaches above the plurality of heat radiating fins 12c through the upstream flow path 14d, and flows into the gaps between the plurality of heat radiating fins 12c therefrom.

As shown in FIG. 7, in the case of the present embodiment, the coolant from the upstream flow path 14d flows into the center in the width direction (Y-axis direction) in the gaps between the plurality of heat radiating fins 12c. Then, the coolant is divided in flow into one side and the other side in the width direction, and flows toward one downstream flow path 14e and the other downstream flow path 14e. At this time, the coolant absorbs heat from the heat absorbing member 12 through the heat transfer surfaces 12d of the plurality of heat radiating fins 12c.

As described above, the coolant flows into the center in the width direction (Y-axis direction) in the gaps between the plurality of heat radiating fins 12c and is divided in flow into the one side and the other side in the width direction, whereby the cooling efficiency of the cooling device 10 is not biased in the width direction. That is, the heat absorbing member 12 of the cooling device 10 can absorb heat from the heating elements W1 and W2 uniformly without bias in the width direction.

Unlike this, when the coolant flows, from one end portion 12f toward the other end portion 12f of the plurality of heat radiating fins 12c, through the gaps between the heat radiating fins 12c, the heat absorbing member 12 can absorb a large amount of heat from the heating elements W1 and W2 at a portion on one side in the width direction, but can absorb only a small amount of heat at a portion on the other side. This is because the more the coolant flows from one end portion 12f toward the other end portion 12f of the plurality of heat radiating fins 12c, the more the temperature thereof is, which generates a temperature gradient of the coolant in the width direction. As a result, a temperature gradient also occurs in the heat absorbing member 12 in the width direction, and a bias occurs in the cooling efficiency of the cooling device 10 in the width direction. The larger the width-direction size of the heat radiating fins 12c, the larger such bias.

The coolant flowing into the gaps between the plurality of heat radiating fins 12c from the upstream flow path 14d absorbs heat through the portion of the heat absorbing member 12.

The downstream flow path 14e is formed in the casing 14 so that the flow path cross-sectional area (cross-sectional area orthogonal to the depth direction (X-axis direction)) of the downstream flow path 14e increases with distance from the outflow port 14c. With this configuration, it is possible to reduce a pressure loss at a place away from the outflow port 14c. When the pressure loss at the place away from the outflow port 14c can be reduced, the difference in the flow rate of the coolant flowing between the heat radiating fins 12c can be reduced. That is, in general, in the process in which the coolant flowing in from the upstream flow path 14d spreads into the downstream flow path 14e, a difference in flow rate of the coolant flowing between the heat radiating fins 12c may occur between the upstream side and the downstream side of the upstream flow path 14d. Specifically, the flow rate of the coolant flowing between the heat radiating fins 12c downstream of the upstream flow path 14d may be insufficient as compared with the coolant flowing between the heat radiating fins 12c upstream of the upstream flow path 14d. When the flow rate of the coolant flowing between the heat radiating fins 12c downstream of the upstream flow path 14d is insufficient as compared with that of the coolant flowing between the heat radiating fins 12c upstream of the upstream flow path 14d, the cooling performance on the downstream side is deteriorated, so that a temperature gradient of the coolant may occur. Examples of the cause that may cause the difference in the flow rate of the coolant include a case where the pressure loss on the downstream side in the upstream flow path 14d is higher than the pressure loss on the upstream side (inflow port 14b side) in the upstream flow path 14d, and therefore the coolant does not sufficiently spread to the downstream side. In this manner, the inflow amount of the coolant decreases as it goes away from the inflow port 14b and goes toward the downstream side in the upstream flow path 14d, and as a result, the cooling performance on the downstream side in the upstream flow path 14d may decrease. As a countermeasure, the downstream flow path 14e is formed in the casing 14 so that the flow path cross-sectional area (cross-sectional area orthogonal to the depth direction (X-axis direction)) of the downstream flow path 14e increases with distance from the outflow port 14c. With this configuration, since the pressure loss on the downstream side in the upstream flow path 14d is reduced, the flow rate of the coolant flowing between the heat radiating fins 12c downstream of the upstream flow path 14d can be made appropriate.

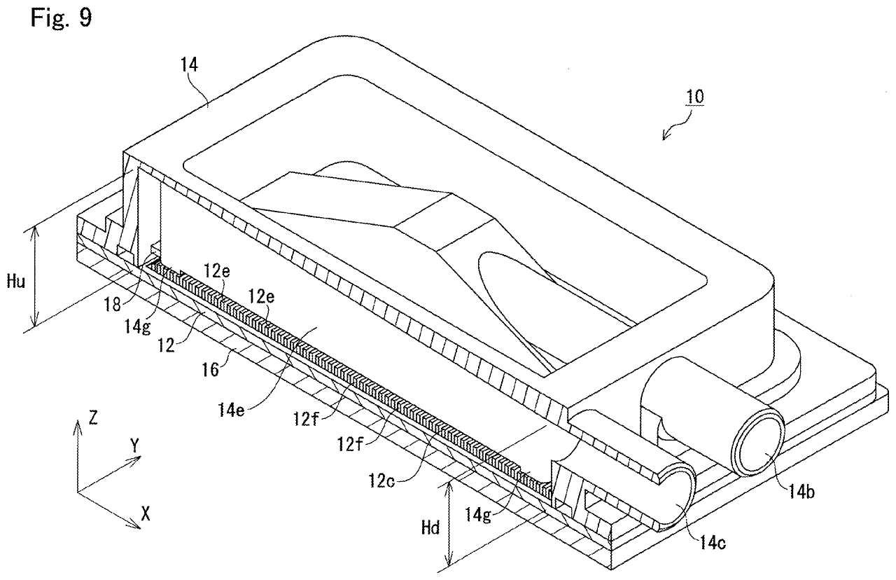

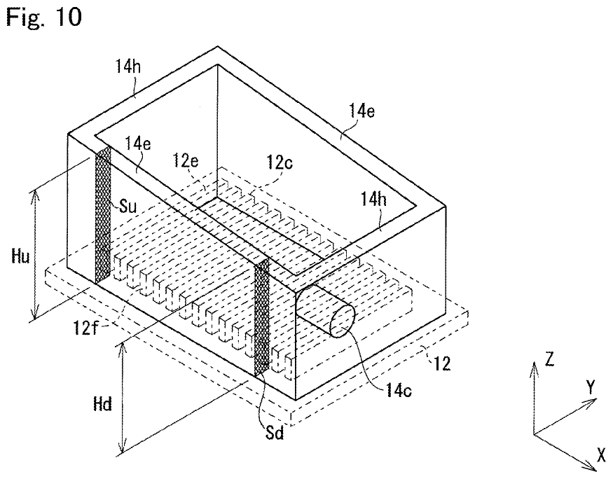

FIG. 9 is a perspective view of the cooling device showing the inside of the downstream flow path. In addition, FIG. 10 is a view schematically showing a shape of the downstream flow path.

As shown in FIGS. 9 and 10, in the downstream flow path 14e, a flow path cross section Sd on the downstream side, that is, closer to the outflow port 14c is smaller than a flow path cross section Su on the upstream side, that is, farther from the outflow port 14c. In the case of the present embodiment, the width (size in the Y-axis direction) is a constant size, and the height (size in the Z-axis direction) increases with distance from the outflow port 14c. That is, the height Hu on the upstream side is larger than the height Hd on the downstream side.

By the downstream flow path 14e having this shape, in the downstream flow path 14e, the pressure loss on the upstream side (that is, the downstream side of the upstream flow path 14d) is mitigated. In the downstream flow path 14e, when the pressure loss on the upstream side is mitigated, the possibility that a difference in the flow rate of the coolant occurs between the upstream side and the downstream side of the upstream flow path 14d is reduced. Accordingly, a sufficient coolant is supplied to the downstream side in the upstream flow path 14d. When a sufficient coolant is supplied to the downstream side in the upstream flow path 14d, as a result, the cooling performance on the downstream side in the upstream flow path 14d is improved (as compared with the case where the flow path cross section of the downstream flow path 14e has a constant size). As a result, occurrence of a large temperature gradient in the depth direction is also suppressed in the heat absorbing member 12, and the cooling device 10 can have uniform cooling efficiency in the depth direction. In the present embodiment, the heating elements W1 and W2 arranged side by side in the depth direction can be cooled with sufficient cooling capacity.

It should be noted that as shown in FIG. 9, the height of the downstream flow path 14e is significantly larger than the heights of the plurality of heat radiating fins 12c. In addition, the plurality of heat radiating fins 12c do not enter the downstream flow path 14e. Therefore, there is a possibility that the coolant flowing out from the gaps between the plurality of heat radiating fins 12c does not sufficiently reach the upper portion of the downstream flow path 14e, and the high-temperature coolant stagnates in the upper portion. As a countermeasure, in the case of the present embodiment, the top portions 12e of the plurality of heat radiating fins 12c are partially exposed to the downstream flow path 14e. Specifically, the portion of the top portion 12e near the end portion 12f in the width direction (Y-axis direction) is exposed to the downstream flow path 14e through the space between the plurality of protruding portions 14g. Accordingly, the coolant flowing through the gaps between the plurality of heat radiating fins 12c is mitigated in pressure before reaching the end portion 12f, and a part of the coolant flows toward the upper portion of the downstream flow path 14e. As a result, the temperature of the coolant is made substantially uniform in the height direction of the downstream flow path 14e.

According to the present embodiment as described above, a cooling device having a configuration capable of changing a layout of an inflow port and an outflow port of a coolant while maintaining high cooling efficiency can be implemented.

More specifically, in the case of the present embodiment, as shown in FIG. 1, the inflow port 14b is provided in a state of arranged side by side with the outflow port 14c at the end portion on one side in the depth direction (X-axis direction) of the casing 14, and faces the depth direction. The layout (position and orientation on the casing 14) of the inflow port 14b can be freely changed. In other words, even when the layout of the inflow port 14b is changed, since the coolant flowing in from the inflow port 14b flows, through the upstream flow path 14d, from the top portion 12e side of the plurality of heat radiating fins 12c into the gaps between the heat radiating fins 12c, the cooling efficiency does not substantially change. Therefore, the inflow port 14b may face the width direction (Y-axis direction) or the height direction (Z-axis direction). In addition, the inflow port 14b can also be provided at an end portion on one side in the width direction of the casing 14. That is, in order to maintain the cooling efficiency, the downstream flow path 14e which extends in the parallel direction (X-axis direction) of the plurality of heat radiating fins 12c and into which the coolant from the end portions 12f of the plurality of heat radiating fins 12c flows only needs to have a larger flow path cross-sectional area as it is further from the outflow port 14c. As a result, it is possible to change the layout of the inflow port 14b and the outflow port 14c of the coolant according to the application of the cooling device 10 while maintaining high cooling efficiency.

As described above, although the present disclosure has been described with reference to the above embodiment, the embodiment of the present disclosure is not limited thereto.

For example, as shown in FIG. 10, in the case of the above-described embodiment, the height (size in the Z-axis direction) of the downstream flow path 14e increases with distance from the outflow port 14c. Accordingly, the flow path cross-sectional area of the downstream flow path 14e is increased with distance from the outflow port 14c. However, the embodiment of the present disclosure is not limited thereto.

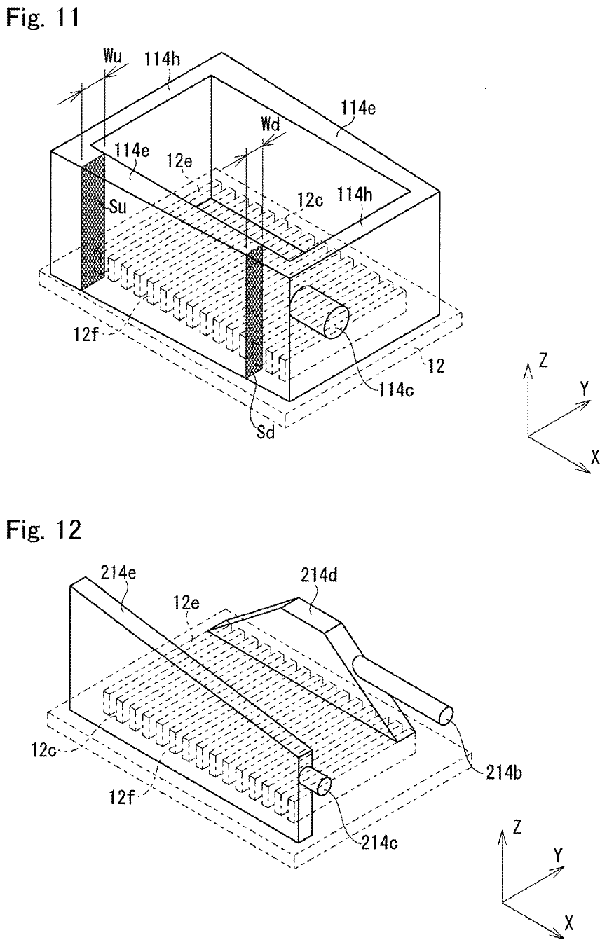

FIG. 11 is a view schematically showing a shape of a downstream flow path in a cooling device according to another embodiment.

As shown in FIG. 11, in the cooling device according to another embodiment, the height (size in the Z-axis direction) of the downstream flow path 114e of the casing is constant. Instead, the width (size in the Y-axis direction) of the downstream flow path 114e increases with distance from the outflow port 14c. That is, the width Wu on the upstream side is larger than the width Wd on the downstream side. Accordingly, the flow path cross section Sd on the downstream side, that is, closer to the outflow port 114c is made smaller than the flow path cross section Su on the upstream side, that is, farther from the outflow port 114c.

It should be noted that both the width and the height of the downstream flow path may be increased with distance from the outflow port. Also with this, the flow path cross-sectional area of the downstream flow path increases with distance from the outflow port. In addition, the flow path cross-sectional area may linearly or stepwise increase as it goes away from the outflow port.

With respect to the flow path cross-sectional area of the downstream flow path, even when the flow path cross-sectional area has a constant size, when the size is sufficient, it is possible to suppress the temperature gradient of the coolant in the extending direction (depth direction (X-axis direction)) to be small in the downstream flow path. However, in this case, a portion of the downstream flow path close to the outflow port is unnecessarily increased in size, and as a result, the cooling device is increased in size.

In addition, for example, in the case of the above-described embodiment, as shown in FIG. 7, the coolant from the upstream flow path 14d flows into the central portion in the width direction (Y-axis direction) in the gaps between the plurality of heat radiating fins 12c. However, the embodiment of the present disclosure is not limited thereto. When the width of the heat radiating fin 12c is small, the coolant may flow into the end portion in the width direction in the gaps between the heat radiating fins.

FIG. 12 is a view schematically showing shapes of an upstream flow path and a downstream flow path in a cooling device according to still another embodiment.

As shown in FIG. 12, in the cooling device according to still another embodiment, the upstream flow path 214d of the casing faces a portion on one side in the width direction (Y-axis direction) in the top portion 12e of the heat radiating fin 12c. In this case, the number of the downstream flow paths 214e is one, and the downstream flow path 214e faces the other end portion 12f in the width direction of the heat radiating fin 12c. According to this cooling device, the coolant flows through the gaps between the plurality of heat radiating fins 12c from one end portion 12f of the heat radiating fin 12c toward the other end portion 12f. This flow of the coolant is available if the cooling efficiency of the cooling device in the width direction is not substantially affected.

That is, in a broad sense, an embodiment according to the present disclosure is a cooling device including: a heat absorbing member including a first surface to which an object to be cooled is to be attached and a second surface opposite to the first surface; a plurality of heat radiating fins provided on the second surface of the heat absorbing member, the plurality of heat radiating fins being arranged along a first direction, the plurality of heat radiating fins each being extending in a second direction orthogonal to the first direction; and a casing attached to a second surface of the heat absorbing member to cover the plurality of heat radiating fins. The casing includes: an inflow port into which a coolant flows, an outflow port from which a coolant flows out, an upstream flow path communicating with the inflow port and facing top portions of the plurality of heat radiating fins, and a downstream flow path communicating with the outflow port, extending in the first direction, and facing end portions in the second direction of the plurality of heat radiating fins. The outflow port is provided at an end portion on one side in the first direction of the casing. A flow path cross-sectional area in the first direction of the downstream flow path increases with distance from the outflow port.

As described above, the embodiments are described as the exemplification of the technique in the present disclosure. To that end, accompanying drawings and detailed description are provided. Therefore, among the components described in the accompanying drawings and the detailed description, not only the components essential for solving the problem, but also the components not essential for solving the problem may be included in order to exemplify the above technique. Therefore, it should not be recognized that these non-essential components are essential immediately because these non-essential components are described in the accompanying drawings and the detailed description.

In addition, since the above preferred embodiments are for exemplifying the technique in the present disclosure, various changes, substitutions, additions, omissions, and the like can be made within the scope of the claims or the equivalent thereof.

### INDUSTRIAL APPLICABILITY

The present disclosure is applicable to a cooling device that cools a heating element using a coolant.

1. A cooling device comprising:
a heat absorbing member;
a heat radiating fin provided on the heat absorbing member; and
a casing attached to cover the heat radiating fin,
wherein the casing includes:
an inflow port into which a coolant flows,
an outflow port from which the coolant flows out, and
a plurality of flow paths, through which the coolant flows, including at least one downstream flow path communicating with the outflow port and facing the heat radiating fin,
wherein the plurality of flow paths is arranged to sandwich the heat radiating fin between the plurality of flow paths.

2. The cooling device according to claim 1,
wherein the casing further includes a connection flow path connecting the plurality of flow paths.

3. The cooling device according to claim 2,
wherein the plurality of flow paths extends in a first direction, and
wherein the connection flow path extends in a direction other than the first direction.

4. The cooling device according to claim 2,
wherein the plurality of flow paths extends in a first direction, and
wherein the connection flow path extends in a direction orthogonal to the first direction.

5. The cooling device according to claim 2,
wherein the casing includes an upstream flow path communicating with the inflow port and facing the heat radiating fin,
wherein the upstream flow path includes a reduced cross-section area portion in which a cross-sectional area is reduced, and
wherein the coolant passing through the reduced cross-section area portion flows into the connection flow path.

6. The cooling device according to claim 1,
wherein the inflow port is provided at an end portion of the casing in a state of being side by side with the outflow port.

7. The cooling device according to claim 1,
wherein the casing includes an upstream flow path communicating with the inflow port and facing the heat radiating fin,
wherein the downstream flow path includes a first deformation portion in which a cross-section area changes as a position in a first direction changes, and
wherein the upstream flow path includes a second deformation portion in which a cross-section area changes as a position in the first direction changes.

8. The cooling device according to claim 7,
wherein the casing further includes a connection flow path connecting the plurality of flow paths, and
wherein the connection flow path includes a constant cross-section area portion in which a cross-sectional area is constant.

9. The cooling device according to claim 1,
wherein an inflow direction of the coolant at the inflow port and an outflow direction of the coolant at the outflow port are different from each other.

10. The cooling device according to claim 2,
wherein the connection flow path is provided between the plurality of flow paths.

11. The cooling device according to claim 1,
wherein the plurality of flow paths extends in a first direction and are provided to sandwich, in a direction different from the first direction, the heat radiating fin between the plurality of flow paths.

12. The cooling device according to claim 1,
wherein the plurality of flow paths extends in a first direction, and
wherein the coolant flows at one end side and the other end side of the casing in a direction different from the first direction.
